(19) United States
(12) Patent Application Publication
(10) Pub. No.: US 2023/0416917 A1
(43) Pub. Date: Dec. 28, 2023

(54) SUBSTRATE PROCESSING APPARATUS

(71) Applicant: WONIK IPS CO., LTD., Pyeongtaek-si Gyeonggi-do (KR)

(72) Inventors: Kee Jun KIM, Osan-si Gyeonggi-do (KR); Seung Han KIM, Hwaseong-si Gyeonggi-do (KR); Bong Su CHOI, Anseong-si Gyeonggi-do (KR); Sang Cheol PARK, Osan-si Gyeonggi-do (KR)

(73) Assignee: WONIK IPS CO., LTD., Pyeongtaek-si Gyeonggi-do (KR)

(21) Appl. No.: 18/081,263

(22) Filed: Dec. 14, 2022

(30) Foreign Application Priority Data
Jun. 27, 2022 (KR) 10-2022-0078339

(51) Int. Cl. C23C 16/455

(52) U.S. Cl. CPC C23C 16/45578

(57) ABSTRACT

The present invention disclosed herein relates to a substrate processing apparatus, and more particularly, to a substrate processing apparatus capable of performing substrate processing such as deposition, etching, and heat processing on a plurality of substrates. The present invention discloses a substrate processing apparatus including a reaction tube having a processing space, in which a plurality of substrates are accommodated to perform substrate processing, a nozzle installation part protruding outward from a portion of a side surface of the reaction tube to provide a portion of an outer surface of the reaction tube, and a plurality of gas injection nozzles disposed along a circumference of each of the substrate in a direction perpendicular to the nozzle installation part to inject a process gas into the reaction tube, wherein the nozzle installation part comprises a plurality of insertion parts corresponding to the gas injection nozzles.

### CROSS-REFERENCE TO RELATED APPLICATIONS

This U.S. non-provisional patent application claims priority under 35 U.S.C. § 119(a) of Korean Patent Application No. 10-2022-0078339, filed on Jun. 27, 2022, in the Korean Intellectual Property Office, the entire contents of which are hereby incorporated by reference.

### FIELD OF THE INVENTION

The present invention disclosed herein relates to a substrate processing apparatus, and more particularly, to a substrate processing apparatus capable of performing substrate processing such as deposition, etching, and heat processing on a plurality of substrates.

### BACKGROUND ART

In order to manufacture a semiconductor element, a process of depositing a thin film on a substrate such as a silicon wafer is essential, and a sputtering method, a chemical vapor deposition (CVD) method, and an atomic layer deposition (ALD) method are mainly used as the process of depositing the thin film.

The sputtering is a technology in which argon ions generated in a plasma state collide with a surface of a target, and a target material separated from the surface of the target is deposited as a thin film on a substrate. The sputtering may have an advantage of forming a high-purity thin film having excellent adhesion, but there is a limit to form a fine pattern having a high aspect ratio.

The chemical vapor deposition method is a technique of depositing the thin film on the substrate by injecting various gases into a reaction chamber and chemically reacting the gases induced by high energy such as thermal light or plasma with a reaction gas.

Since the chemical vapor deposition method uses the chemical reaction that occurs quickly, it is very difficult to control thermodynamic stability of atoms, and there is a limitation in that the physical, chemical, and electrical properties of the thin film are deteriorated.

The atomic layer deposition is a technology for depositing a thin film in atomic layer units on a substrate by alternately supplying a processing gas and a purge gas, which are reaction gases. Since the atomic layer deposition uses surface reaction to overcome a limitation of step coverage, it is suitable for forming a micro pattern with a high aspect ratio and has excellent electrical and physical properties of the thin film.

As an apparatus for performing the atomic layer deposition method, there are a single wafer type apparatus in which a process is performed while loading substrates in a chamber one by one, and a batch type apparatus in which a plurality of substrates are loaded into a chamber and processed in batches.

Here, in general, in the batch type substrate processing apparatus, an injection nozzle installation position protruding outward is defined inside a reaction tube, and a plurality of gas injection nozzles are installed at the injection nozzle installation position to inject a process gas, thereby performing the substrate processing.

In this case, a dead volume is formed at the injection nozzle installation position at which a plurality of gas injection nozzles are installed, and various process gases, in particular, a source gas and a reaction gas remain, resulting in various byproducts in the reaction tube and causing particle factors.

In addition, as the various process gases remain in the dead volume at the injection nozzle installation position, there are limitations in that a flow rate of the injected process gas is not sufficient, the substrate processing is not smoothly performed due to a difference in flow rate depending on the position of the process gas injected toward the processing space, and uniformity is lowered.

### SUMMARY OF THE INVENTION

To solve the above-mentioned limitations, the present invention provides a substrate processing apparatus capable of preventing and minimizing a gas remaining near a nozzle.

In accordance with an embodiment of the present invention, disclosed is a substrate processing apparatus including: a reaction tube (100) having a processing space (S1), in which a plurality of substrates (1) are accommodated to perform substrate processing: a nozzle installation part (200) protruding outward from a portion of a side surface of the reaction tube (100) to provide a portion of an outer surface of the reaction tube (100); and a plurality of gas injection nozzles (300) disposed along a circumference of each of the substrate (1) in a direction perpendicular to the nozzle installation part (200) to inject a process gas into the reaction tube (100), wherein the nozzle installation part (200) comprises a plurality of insertion parts corresponding to the gas injection nozzles (300) so that each of the gas injection nozzles (300) is inserted and installed.

The insertion parts may include a plurality of insertion grooves (210), each of which has a shape corresponding to an outer surface of the gas injection nozzle (300) in an inner wall toward the processing space (S1) so that the gas injection nozzle (300) is inserted and installed.

The insertion parts may include through-holes (220), each of which is penetrated in a vertical direction so that each of the gas injection nozzles (300) is installed therein.

The nozzle installation part (200) may include an injection port configured to allow the processing space (S1) and the through-hole (220) to communicate with each other.

The injection port may include a plurality of injection holes (290), each of which is defined at a position corresponding to a gas injection hole (301) defined in the gas injection nozzle (300).

The injection port may include an injection slit (280) defined in the vertical direction with a width less than a diameter of the gas injection nozzle (300) at a position corresponding to each of the plurality of gas injection holes (301) which are defined in a direction perpendicular to the gas injection nozzle (300).

The through-hole (220) may have a shape corresponding to that of an outer surface of the gas injection nozzle (300).

The gas injection nozzles (300) may be inserted and installed to be spaced apart from an inner wall of each of the insertion parts corresponding thereto.

The nozzle installation part (200) may have an inner surface that extends at the same curvature as an inner surface of the reaction tube (100).

A first distance (D1) that is the shortest horizontal distance between an inner surface of the nozzle installation part (200) and a center (C) of the reaction tube (100) may be the same as a second distance (D2) that is the shortest distance from a position of the inner surface of the reaction tube (100) excluding the nozzle installation part (200) to the center (C).

The nozzle installation part (200) may include: a pair of protrusion surfaces (230) provided to protrude outward from a side surface of the reaction tube (100); and an outer surface portion (240) defined between the protrusion surfaces (230).

The nozzle installation part (200) may include an installation member (270) which is installed on an area surrounded by the pair of protrusion surfaces (230) and the outer surface portion (240) and in which a plurality of insertion parts are defined in an inner surface toward the processing space (S).

In the nozzle installation part (200), the pair of protrusion surfaces (230) and the outer surface portion (240) may be disposed on an outer surface of the nozzle installation part (200), and the plurality of insertion parts may be integrated with each other on the inner surface toward the processing space (S1).

The outer surface portion (240) may have the same curvature as an outer surface of the reaction tube (100).

The reaction tube (100) may include an exhaust port (120) provided at a position facing the nozzle installation part (200).

The reaction tube (100) may be disposed to be line symmetric with respect to a virtual horizontal line connecting a center of the exhaust port (120) to a center of the nozzle installation part (200) on a plane.

The gas injection nozzles (300) may be disposed to inject the process gas so that the plurality of gas injection holes (301) defined in the vertical direction are parallel to each other.

The substrate processing apparatus may further include an outer tube (400) into which the reaction tube (100) is accommodated to define an exhaust space (S2) between the outer tube (400) and the reaction tube (100).

A side surface of the outer tube (400), an inner surface of the nozzle installation part (200), and a side surface of the reaction tube (100) may have the same curvature as each other.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating a configuration of a substrate processing apparatus according to the present invention:

FIG. 2 is a cross-sectional view illustrating a configuration of the substrate processing apparatus of FIG. 1:

FIG. 3 is a cross-sectional view illustrating a configuration of the substrate processing apparatus of FIG. 1;

FIG. 4 is an enlarged cross-sectional view illustrating a configuration of a nozzle installation part in the substrate processing apparatus of FIG. 4:

FIG. 5 is an enlarged cross-sectional view illustrating a nozzle installation part in a substrate processing apparatus according to another embodiment of the present invention;

FIG. 6 is a view illustrating a configuration of an injection hole in the substrate processing apparatus of FIG. 5;

FIG. 7 is a view illustrating a configuration of an injection slit in the substrate processing apparatus according to the present invention;

FIG. 8 is an enlarged cross-sectional view illustrating a nozzle installation part in a substrate processing apparatus according to another embodiment of the present invention; and

FIGS. 9A to 9C are graphs illustrating an effect of the substrate processing apparatus of FIG. 1, wherein FIG. 9A is a graph illustrating a residual gas concentration over time at a position of a substrate that is adjacent to a gas nozzle part; FIG. 9B is a graph illustrating a residual gas concentration over time at a position of the substrate that is adjacent to an exhaust port; and FIG. 9C is a graph illustrating the residual gas concentration over time in the exhaust tube part.

### DETAILED DESCRIPTION OF THE PREFERRED EMBODIMENTS

Hereinafter, a substrate processing apparatus according to the present invention will be described in detail with reference to the accompanying drawings.

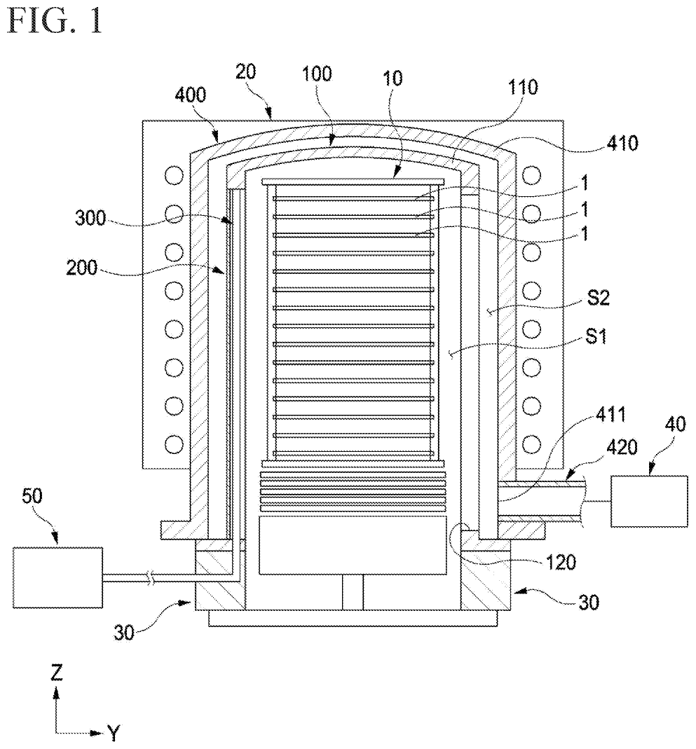

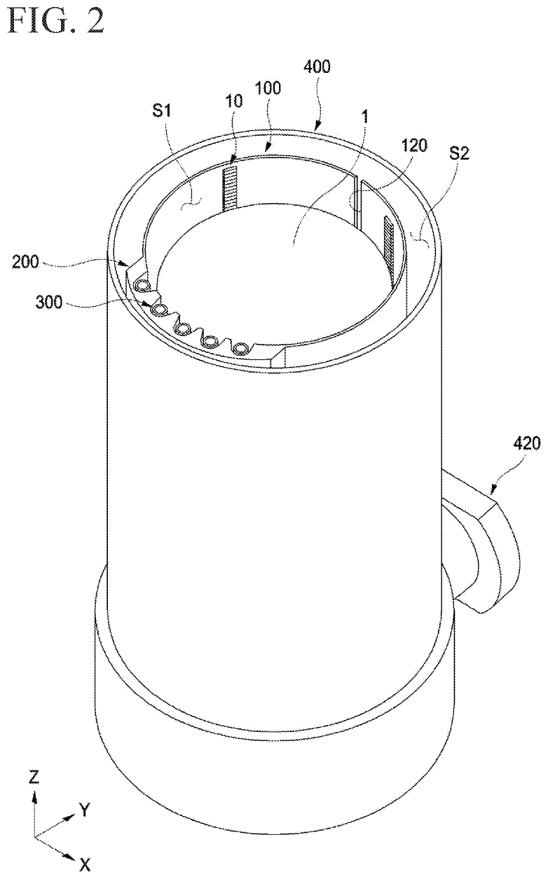

As illustrated in FIGS. 1 and 2, a substrate processing apparatus according to the present invention includes a reaction tube 100 having a processing space SL, in which a plurality of substrates 1 are accommodated to perform substrate processing, a nozzle installation part 200 protruding outward from a portion of a side surface of the reaction tube 100 to provide a portion of an outer surface of the reaction tube 100, and a plurality of gas injection nozzles 300 disposed along a circumference of the substrate 1 in a direction perpendicular to the nozzle installation part 200 to inject a process gas into the reaction tube 100.

In addition, the substrate processing apparatus according to the present invention may further include an outer tube 400 in which the reaction tube 100 is accommodated to define an exhaust space S2 between the internal reaction tube 100 and the outer tube 400.

In addition, the substrate processing apparatus according to the present invention may further include a substrate loading part 10 accommodated in the processing space S1 so that the plurality of substrates 1 are stacked to perform the substrate processing on the plurality of substrates 1.

In addition, the substrate processing apparatus according to the present invention may further include a manifold 30 coupled to a lower side of the reaction tube 100 and provided with an injector connected to a gas injection nozzle 300 to be described later to supply a process gas to the gas injection nozzle 300.

Here, the substrate 1 to be subjected to the substrate processing may include a semiconductor substrate, a substrate used for display devices such as an LED and an LCD, a solar cell substrate, a glass substrate, and the like, and any type of previously disclosed target substrate may be applied to the substrate 1.

In addition, the substrate processing means a deposition process, more preferably a deposition process using atomic layer deposition (ALD), but is not limited thereto and may include a deposition process using chemical vapor deposition, a heat processing process, and the like.

The process gas may be a gas supplied and injected for the substrate processing performed in the processing space S1 and may include a purge gas, a source gas, and a reaction gas that are respectively injected through a plurality of gas injection nozzles 300 to be described later.

The substrate loading part 10 has a configuration in which the plurality of substrates 1 are stacked and may have various configurations.

For example, the substrate loading part 10 may include a plurality of supports provided in a vertical direction and a seating part for allowing the plurality of substrates 1 to be seated on the support in a stacked form.

The substrate loading part 10 may be applied to any configuration as long as the substrate loading part 10 is a configuration used in a batch type that is disclosed in the related art, i.e., a vertical type substrate processing apparatus.

The manifold 30 may be disposed to be coupled to a lower side of the reaction tube 100 and be provided with an injector connected to a process gas supply part 50 disposed at the outside, fixing the gas injection nozzle 300 to be described later, and connected to the injector to induce and supply the process gas to the gas injection nozzle 300.

That is, the manifold 30 may be provided in plurality through which injectors corresponding to the plurality of gas injection nozzles 300 pass. Here, a lower end of the gas injection nozzle 300 may be coupled to each of the injectors to supply the process gas to the gas injection nozzle 300.

The reaction tube 100 may have the processing space S1 in which the plurality of substrates 1 are accommodated to perform the substrate processing, and an opening 101 is defined in a portion of a sidewall, and may have various configurations.

For example, the reaction tube 100 may include a main body 110 having the opening 101 defined at one side of the sidewall and an exhaust port 120 provided on the other side of the sidewall of the main body 110.

Here, the reaction tube 100 may be made of a quartz material and have an upper end provided in a dome shape. For another example, the reaction tube 100 may be provided as a plane.

The exhaust port 120 may be configured to exhaust the processing space S1 and thus perform the exhaust of the exhaust gas including the process gas supplied through the gas injection nozzle 300 to be described later and various byproducts generated thereby. Here, the exhaust may mean exhaust from the processing space S1 to an exhaust space S2 defined through the outer tube 400 to be described later.

That is, the exhaust port 120 may perform the exhaust from the processing space S1 to the exhaust space S2.

The exhaust port 120 may be provided at a position adjacent to a main exhaust port 411 as a position corresponding to the main exhaust port 411 on a plane among side surfaces of the reaction tube 100.

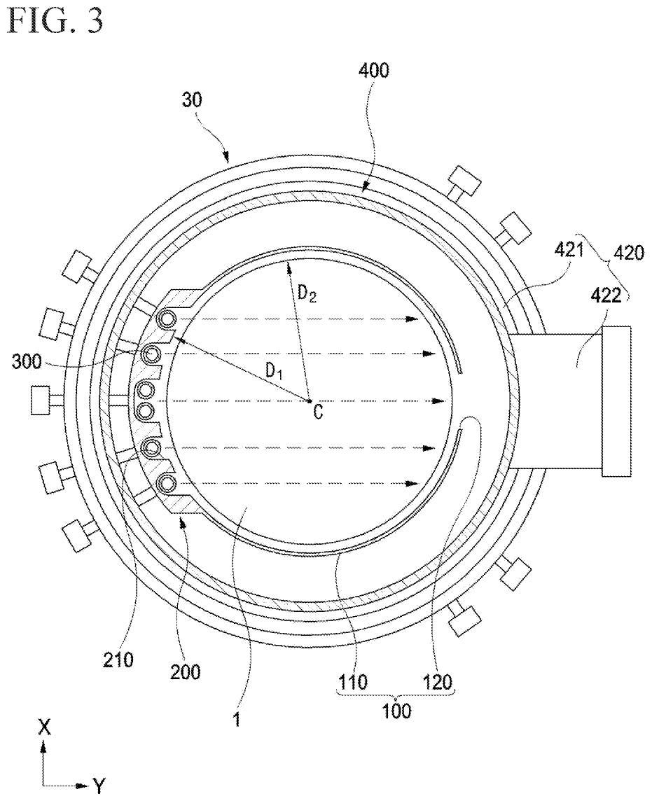

More particularly, as illustrated in FIG. 3, the exhaust port 120 may be disposed at a position opposite to the gas injection nozzle 300 and adjacent to the main exhaust port 411 among the side surfaces of the reaction tube 100.

For example, the exhaust port 120 may be provided in a vertical slit shape in the sidewall of the reaction tube 100, and more particularly, the substrates 1 stacked vertically on the sidewall of the reaction tube 100 may be disposed with a length in the vertical direction of a height corresponding to the highest height and the lowest height.

The process gas exhausted to the exhaust space S2 through the exhaust port 120 may be discharged to the outside through the main exhaust port 411 to be described later. Here, as the main exhaust port 411 is provided below the sidewall of the outer tube 400, a downward flow of the process gas exhausted through the exhaust port 120 may occur.

In order to compensate for such the downward flow, an exhaust amount per hour at an upper side of the reaction tube 100 may be induced to be greater than that at a lower side of the lower side.

For this, when the exhaust port 120 is provided as a slit in the vertical direction in the sidewall of the reaction tube 100, the exhaust port 120 may have a width that is gradually or stepwisely widen as it goes upward.

In addition, for another example, the exhaust port 120 may be a plurality of exhaust holes defined to be spaced apart from each other in the vertical direction in the sidewall of the reaction tube 100. Here, an area of the exhaust holes may gradually or stepwisely increase toward the upper side.

The reaction tube 100 may include an opening 101 in which a portion of the sidewall is opened, and a nozzle installation part 200 to be described later is provided. Here, the nozzle installation part 200 may cover the opening 101 and be coupled to define an outer surface.

Here, the opening 101 may be defined at a position facing the exhaust port 120, and more particularly, the inside of the reaction tube 100 may be disposed to be line symmetric with respect to a virtual horizontal line connecting a center of the exhaust port 120 to a center of the opening 101 on a plane.

That is, the opening 101 and the exhaust port 120 may be disposed at positions facing each other, and thus, the line symmetry may be achieved with respect to the virtual horizontal line connecting the center of the nozzle installation part 200 to the center of the opening 101.

Here, an object of the line symmetry may include not only the nozzle installation part 200, the opening 101, and the exhaust port 120, but also the reaction tube body 110, the installed gas injection nozzle 300, and the insertion part.

The nozzle installation part 200 may protrude outward from the opening 101 to define a portion of the outer surface of the reaction tube 100 and may have various configurations.

Particularly, the nozzle installation part 200 is provided with a plurality of insertion parts corresponding to the gas injection nozzles 300 so that the gas injection nozzles 300 are inserted and installed, respectively.

That is, in a state of being provided to protrude outward from a portion of the side surface of the reaction tube 100, the nozzle installation part 200 may induce the gas injection nozzle 300 to be inserted and installed in the insertion part so that the gas injection nozzle 300 is a configuration capable of minimizing a dead volume generated for installation.

For this, the nozzle installation part 200 may be a configuration in which the insertion part, into which each of the gas injection nozzles 300 is inserted and installed, is provided to occupy a volume and may be provided with a body 201 in which an empty space except for the insertion part to be described is not defined therein.

Here, the nozzle installation part 200 may be provided to be integrated with the reaction tube 100, and for another example, the nozzle installation part 200 may be installed at both ends of the opening 101 through welding or the like.

The nozzle installation part 200 may be made of the same material as the reaction tube 100 described above, and the insertion part may be provided inside the reaction tube 100 to secure an installation space for the gas injection nozzle 300.

Here, the nozzle installation part 200 may have an inner surface extending from an inner surface of the reaction tube 100 so that the inner surfaces have the same curvature.

That is, the nozzle installation part 200 may have an inner surface extending from the opening 101 to the inner surface of the reaction tube 100 to have the same curvature. For another example, the inner surface of the nozzle installation part 200 has the same curvature as the inner surface of the reaction tube 100, but is discontinuous without extending from the inner surface of the reaction tube 100.

Here, in the nozzle installation part 200, a first distance D1, which is the shortest horizontal distance between the inner surface excluding the position at which the insertion part is disposed and a center C of the reaction tube 100, and a second distance D2, which is the shortest horizontal distance from the center C to the inner surface of the reaction tube 100 may be the same.

In this case, the second distance D2 may refer to the shortest horizontal distance between the centers C at the position excluding an area of the inner surface of the reaction tube 100, on which the nozzle installation part 200 is disposed.

That is, the inner surface of the nozzle installation part 200 may extend with the inner surface of the reaction tube 100 to provide a circular shape with the inner surface of the reaction tube 100 on the plane.

The nozzle installation part 200 may protrude outward from both ends of the opening 101 to provide a pair of protrusion surfaces 230, and an outer surface portion 240 may be disposed between the protrusion surfaces 230 to provide a portion of the outer surface of the reaction tube 100.

Here, the pair of protrusion surfaces 230 may be provided by protruding outward from the opening 101 of the reaction tube 100, i.e., at a preset position and be coupled to the opening 101 through welding or the like.

Each of the pair of protrusion surfaces 230 may protrude in a radial direction of the reaction tube 100, i.e., in a direction connecting positions on a circumference from the center C. For another example, as illustrated in FIG. 3, the pair of protrusion surfaces 230 may protrude in a direction parallel to the injection direction of the gas injection nozzle 300 to be described later.

In addition, the outer surface portion 240 may be provided at the same curvature as the outer surface of the reaction tube 100, and furthermore, be provided at the same curvature as the outer tube 400 described later so that a horizontal distance from an arbitrary position to the outer tube 400 is uniformly maintained.

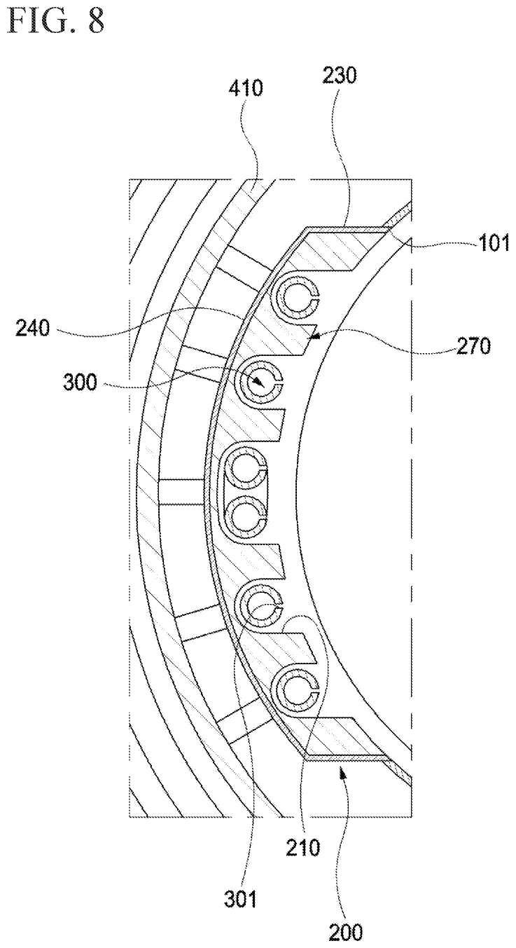

In this case, for example, as illustrated in FIG. 8, the nozzle installation part 200 may be installed on an area surrounded by the pair of protrusion surfaces 230 and an outer surface portion 240 and may include an installation member 270 in which a plurality of insertion parts are provided, on an inner surface toward the processing space S1.

That is, in the nozzle installation part 200, a pair of protrusion surfaces 230 extending from the reaction tube 100 to protrude toward an outer surface and an outer surface portion 240 disposed to provide an outer surface between the pair of protruding surfaces 230 may be provided to define an empty space surrounded by the pair of protrusion surfaces 230 and the outer surface portion 240.

The installation member 270 may be a configuration that is installed to be coupled to the pair of protrusion surfaces 230 and the outer surface portion 240 in the empty space surrounded by the pair of protrusion surfaces 230 and the outer surface portion 240, and a plurality of insertion parts are provided toward the processing space S1 to remove the dead volume.

In addition, the installation member 270 may be easily changed and installed as a configuration in which the insertion parts corresponding to the number, size, and position of the gas injection nozzles 300 are changed through a relatively simple coupling structure so that the dead volume is optimized and eliminated even when various specifications of the gas injection nozzle 300 are changed.

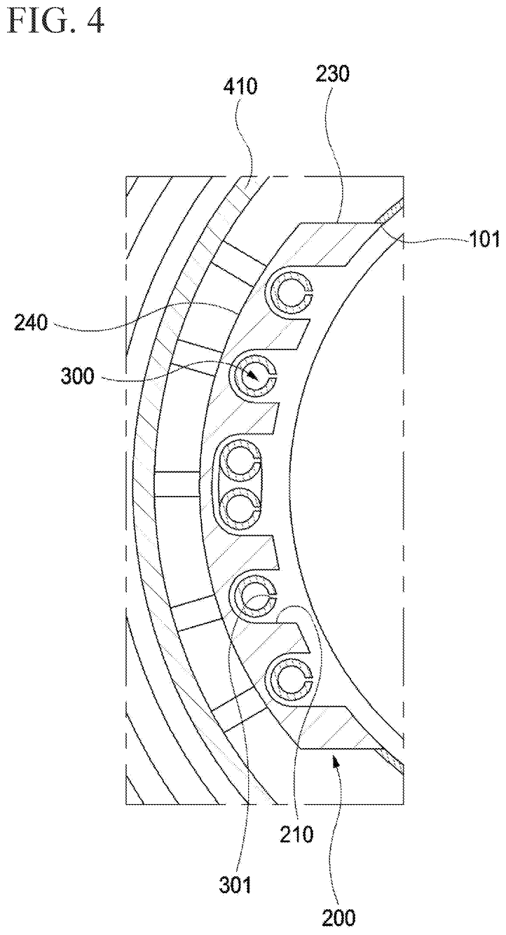

In addition, for another example, as illustrated FIG. 4, the nozzle installation part 200 may be a configuration in which a pair of protrusion surfaces 230 and an outer surface portion 240 are disposed on the outer surface, and the plurality of insertion parts are integrally disposed on the inner surface toward the processing space S1.

As illustrated in FIGS. 3 and 4, for example, the insertion parts may be insertion grooves 210 provided in a shape corresponding to that of the outer surface of the gas injection nozzle 300 on the inner wall toward the processing space S1 so that the gas injection nozzle 300 is inserted and installed.

The insertion groove 210 may be defined to correspond to each of the plurality of gas injection nozzles 300 on the inner wall toward the processing space S1 of the body 201 and may be spaced apart from each other in the vertical direction.

Here, the insertion groove 210 may be provided in a shape corresponding to the outer surface of the gas injection nozzle 300, and more specifically, may be provided to be vertically elongated in a circular concave groove shape corresponding to the gas injection nozzle 300 having a vertical length having a cylindrical shape.

The insertion groove 210 may be provided to correspond to the outer surface of the gas injection nozzle 300, and when the gas injection nozzle 300 has an angular polygonal shape, the insertion groove 210 may be provided as a groove having a corresponding shape.

In addition, the insertion groove 210 may be provided in a size corresponding to the gas injection nozzle 300 so that the gas injection nozzle 300 does not protrude outward and may have a diameter greater than that of the gas injection nozzle 300 so as to be inserted toward the processing space S1.

Furthermore, when the gas injection nozzle 300 is installed to be in contact with the insertion groove 210, various vibrations may occur due to characteristics of the gas injection nozzle 300, which has a length in the vertical direction and is coupled only at the lower side, to collide with the insertion groove 210 and thus be damaged. Thus, the contact between the insertion groove 210 and the gas injection nozzle 300 may be spaced a predetermined interval from each other to prevent the insertion groove 210 and the gas injection nozzle 300 from being in contact with each other and have a size corresponding thereto.

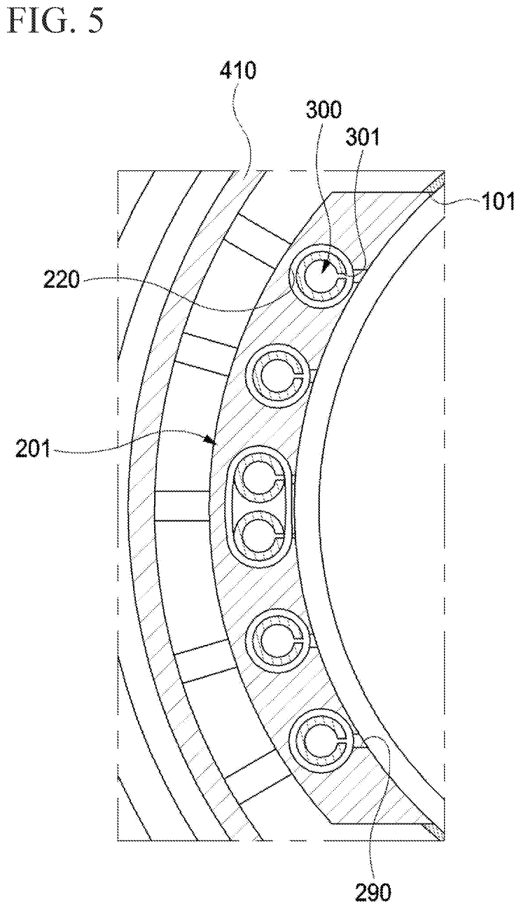

For another example, as illustrated in FIG. 5, the insertion portion may be a through-hole 220 which is penetrated in the vertical direction and to which each of the gas injection nozzles 300 is installed.

That is, the insertion part may be a through-hole 220 defined to pass through the body 201 in the vertical direction, and the gas injection nozzle 300 may be inserted and installed in the body 201 in the vertical direction from an upper or lower side to the through-hole 220.

In this case, the through-hole 220 may be provided in a shape corresponding to the outer surface of the gas injection nozzle 300 and prevent the process gas from being permeated from the processing space S1 while injecting the process gas through the injection port having a diameter less than that of the gas injection nozzle 300, thereby minimizing an occurrence of a residual gas within the through-hole 220.

Here, the nozzle installation part 200 may include the injection port through which the processing space S1 and the through-hole 220 communicate with each other so that the process gas is injected through the gas injection nozzle 300 installed in the through-hole 220.

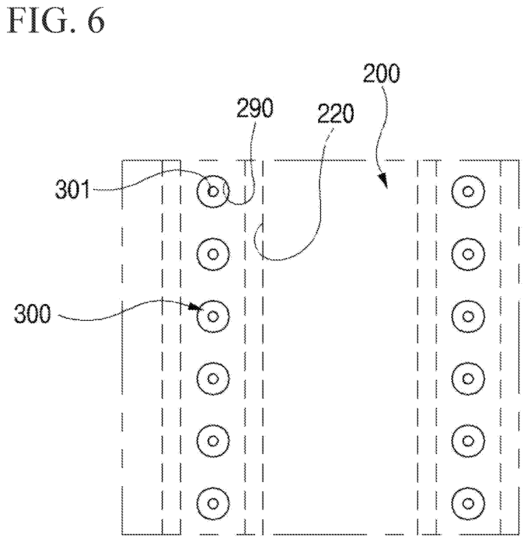

For example, as illustrated in FIGS. 5 and 6, the injection port may be a plurality of injection holes 290 having a hole shape defined in a position corresponding to the gas injection hole 301 defined in the gas injection nozzle 300.

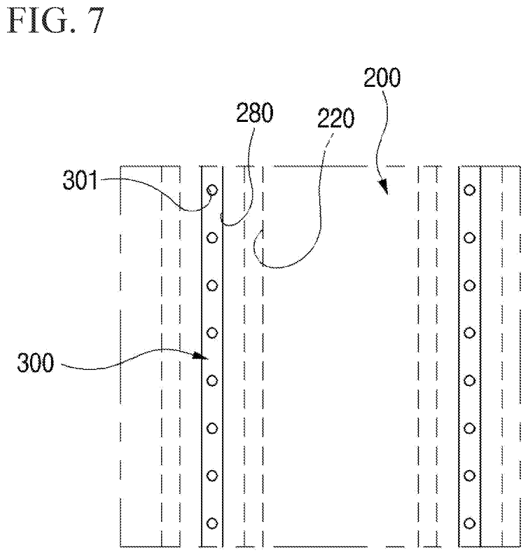

In addition, for another example, as illustrated in FIG. 7, the injection port may be an injection slit 280 defined in the vertical direction, which has a width less than the diameter of the gas injection nozzle 300 at the position corresponding to each of the plurality of gas injection holes 301 defined in the gas injection nozzle 300 in the vertical direction.

That is, the injection port may be a configuration through which the through-hole 220 and the processing space S1 communicate with each other so that the process gas injected through the gas injection hole 301 is appropriately injected into the processing space S1 and may include the injection hole 290 and the injection slit 280.

The gas injection nozzle 300 may be disposed along a circumference of the substrate 1 in a direction perpendicular to the nozzle installation part 200 to inject the process gas into the reaction tube 100 and may have various configurations.

Here, the gas injection nozzle 300 may be installed by being inserted into the insertion part of the nozzle installation part 200 so as to be disposed adjacent to the inner surface of the nozzle installation part 200. Thus, the process gas injected from the gas injection nozzle 300 may generate a straight airflow toward the exhaust port 120 provided at the opposite position and then be injected.

The gas injection nozzles 300 may be provided in plurality to inject a source gas, a reaction gas, and an inert gas as the above-described process gas, and each of the plurality of gas injection nozzles 300 may inject a predetermined gas.

In this case, in the gas injection nozzle 300, the gas injection nozzle 300 for injecting the source gas and the reaction gas may be disposed at a central side, and the gas injection nozzle 300 from which the inert gas is injected may be disposed in the vicinity of the gas injection nozzle 300 so that the source gas and the reaction gas is enhanced in straightness through the guide role of the inert gas and then is injected.

In addition, as illustrated in FIG. 3, the plurality of gas injection nozzles 300 may inject the source gas, the reaction gas, and the process gas of the purge gas in the same direction to induce air currents parallel to each other, and thus, the process gas may flow in the same direction in the processing space S1.

More particularly, in the plurality of gas injection nozzles 300, the plurality of gas injection holes 301 defined in the vertical direction may be provided in the same direction with respect to each gas injection nozzle 300, and the plurality of gas injection holes 301 may be provided in the same direction to induce the process gas on the substrate 1, thereby flowing in the same direction, i.e., from the nozzle installation part 200 toward the exhaust port 120 in parallel to each other.

The gas injection nozzle 300 may simply have a length in the vertical direction and may have a configuration in which the plurality of gas injection holes 301 are defined in an outer circumferential surface.

In addition, for another example, the gas injection nozzle 300 may have an inverted “U” shape as a whole and may include a first injection nozzle of which one end is connected to an injector supplying the process at a lower portion of the reaction tube 100 and in which a plurality of gas injection holes 301 are defined in the vertical direction, a second injection nozzle disposed parallel to the first injection nozzle to define the plurality of gas injection holes 301 in the vertical direction, and a connection portion connecting the other end of the first injection nozzle to the second injection nozzle.

In this case, the second injection nozzle may be disposed in parallel to the first injection nozzle at a position adjacent to the substrate loading part 10 and may be disposed at a height corresponding to a loading range of the substrates 10 loaded on the substrate loading part 10.

The plurality of gas injection holes 301 may be defined in plurality, which are spaced apart from each other in the vertical direction, disposed at regular intervals from each other, or defined to correspond to the loading positions of the substrates 1.

The outer tube 400 further including an outer tube 400 in which the reaction tube 100 is accommodated, and the exhaust space S2 is defined between the reaction tube 100 and the reaction tube 100 may be a configuration in which the reaction tube 100 is accommodated to define the exhaust space S2 between internal reaction tube 100 and the outer tube 400, and a main exhaust port 411 is provided to exhaust the exhaust gas transmitted from the processing space S1 through the exhaust port 120 to the outside and may have various configurations.

The outer tube 400 may be made of a quartz material and may have a domed upper end. For another example, the outer tube 400 may be provided as a plane and may have a circular shape on the plane.

Since the main exhaust port 411 is disposed at a lower side of the outer tube 400, the outer tube 400 may be introduced to apply a double tube structure to improve the limitation in which the horizontal air flow of the process gas is not be maintained, and smooth substrate processing is not performed as the air flow is generated to the lower side at which the main exhaust port 411 is disposed.

Thus, the outer tube 400 may accommodate the reaction tube 100 therein to define the exhaust space S2 between the reaction tube 100 and the outer tube 400.

Here, the main exhaust port 411 provided at the lower side of the outer tube body 410 may be configured to exhaust the exhaust gas transmitted to the exhaust space S2 through the exhaust port 120 to the outside and may have various configurations.

For example, the main exhaust port 411 may be provided at the lower side of the outer tube body 410, and the exhaust may be performed through a pump 40 disposed outside.

Here, the main exhaust port 411 may be disposed at an appropriate position among the side surfaces of the outer tube body 410, but may be disposed at the lower side of the side surface in consideration of a heater part 20 provided outside an outer tube body 410.

Here, the main exhaust port 411 may be provided to pass through the outer tube 400 and may be provided in a circular shape corresponding to an exhaust tube part 420 to be described later.

The outer tube 400 may further include an exhaust tube part 420 installed at a position corresponding to the main exhaust port 411.

The exhaust tube part 420 may be installed in the outer tube 400 to discharge the exhaust gas exhausted through the main exhaust port 411 to the outside and may be connected to the external pump 40 for this purpose.

For example, the exhaust tube portion 420 may include a coupling part 421 installed to surround the lower outer circumferential surface of the outer tube 400, and an exhaust tube 422 disposed at a position corresponding to the main exhaust port 411 from the coupling portion 421.

In this case, a side surface of the outer tube 400, an inner surface of the nozzle installation part 200, and a side surface of the reaction tube 100 may be provided at the same curvature as a circular shape on the plane, and for another example, may be provided in a shape corresponding so that the horizontal distance that is the shortest distance at the an arbitrary position is uniformly maintained.

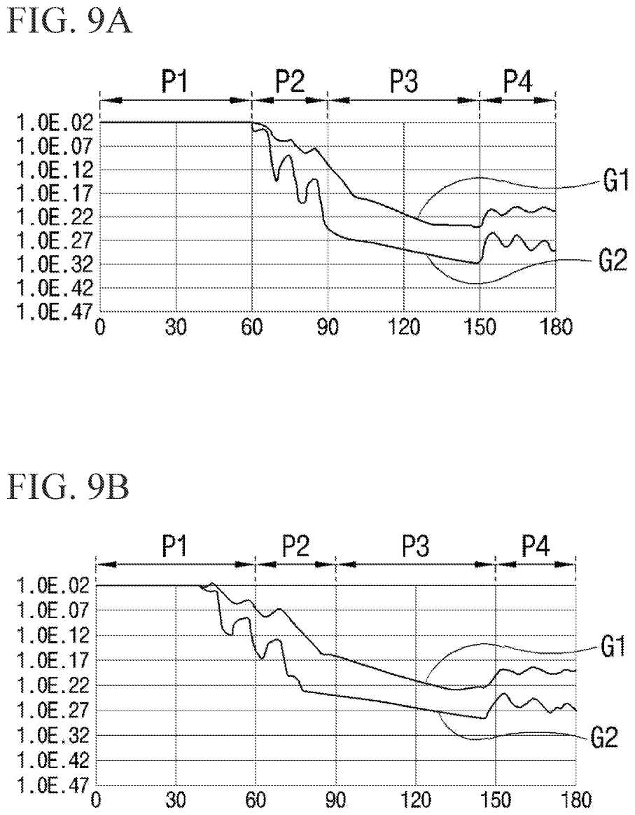

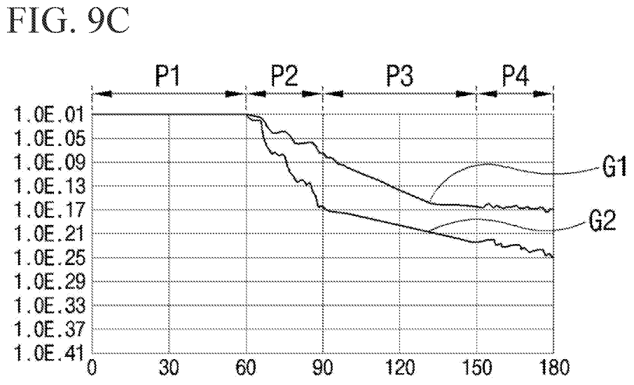

Hereinafter, effects of the substrate processing apparatus according to the present invention will be described with reference to FIGS. 9A to 9C.

The substrate processing apparatus according to the present invention has an advantage of improving substrate processing quality by reducing a residual gas by minimizing a separate space at a position at which the gas injection nozzle 300 is installed.

Particularly, FIGS. 9A, 9B, and 9C illustrate a position closest to the gas injection nozzle 300 on the substrate 1, a position closest to the exhaust port 120 on the substrate 1, and graphs showing a residual gas concentration of the source gas in the substrate processing process using ALD according to one embodiment of the present invention in the main exhaust port 411.

In each graph, G1 is a graph showing a residual gas concentration of the source gas according to the substrate processing apparatus according to the related art, and G2 is a graph showing a residual gas concentration of the source gas in the substrate processing apparatus according to the present invention.

Here, an X-axis of each graph means a time, a Y-axis means an amount of residual gas, P1 is a period in which the source gas is introduced, P2 is a purge period, P3 is a period in which the reaction gas is introduced, and P4 means a purge period.

Looking at each drawings, it is seen that the residual gas of the source gas is reduced compared to the substrate processing apparatus according to the related art at each position, which is seen as the main position. Thus, there is an advantage in that the amount of residual gas is significantly reduced to prevent the residual gas from acting as various byproducts, thereby deteriorating the substrate processing quality, and inducing the uniform substrate processing by securing injection uniformity.

The substrate processing apparatus according to the present invention may have the advantage of preventing and minimizing the remaining residual gas in the vicinity of the gas injection nozzle by minimizing the dead volume around the gas injection nozzle.

In addition, the substrate processing apparatus according to the present invention may have the advantage of being capable of smoothly purging the residual gas disposed near the gas injection nozzle by minimizing the dead volume around the gas injection nozzle.

In addition, the substrate processing apparatus according to the present invention may have the advantage of improving the quality such as the substrate processing uniformity and the step coverage by minimizing the residual gas in the reaction tube.

Although the above description merely corresponds to some exemplary embodiments that may be implemented by the present invention, as well known, the scope of the present invention should not be interpreted as being limited to the above-described embodiments, and all technical spirits having the same basis as that of the above-described technical spirit of the present invention are included in the scope of the present invention.

What is claimed is:

1. A substrate processing apparatus comprising:
a reaction tube having a processing space, in which a plurality of substrates are accommodated to perform substrate processing;
a nozzle installation part protruding outward from a portion of a side surface of the reaction tube to provide a portion of an outer surface of the reaction tube; and
a plurality of gas injection nozzles disposed along a circumference of each of the substrate in a direction perpendicular to the nozzle installation part to inject a process gas into the reaction tube,
wherein the nozzle installation part comprises a plurality of insertion parts corresponding to the gas injection nozzles so that each of the gas injection nozzles is inserted and installed.

2. The substrate processing apparatus of claim 1, wherein the insertion parts comprise a plurality of insertion grooves, each of which has a shape corresponding to an outer surface of the gas injection nozzle in an inner wall toward the processing space so that the gas injection nozzle is inserted and installed.

3. The substrate processing apparatus of claim 1, wherein the insertion parts comprise through-holes, each of which is penetrated in a vertical direction so that each of the gas injection nozzles is installed therein.

4. The substrate processing apparatus of claim 3, wherein the nozzle installation part comprises an injection port configured to allow the processing space and the through-hole to communicate with each other.

5. The substrate processing apparatus of claim 4, wherein the injection port comprises a plurality of injection holes, each of which is defined at a position corresponding to a gas injection hole defined in the gas injection nozzle.

6. The substrate processing apparatus of claim 4, wherein the injection port comprises an injection slit defined in the vertical direction with a width less than a diameter of the gas injection nozzle at a position corresponding to each of the plurality of gas injection holes which are defined in a direction perpendicular to the gas injection nozzle.

7. The substrate processing apparatus of claim 3, wherein the through-hole has a shape corresponding to that of an outer surface of the gas injection nozzle.

8. The substrate processing apparatus of claim 1, wherein the gas injection nozzles are inserted and installed to be spaced apart from an inner wall of each of the insertion parts corresponding thereto.

9. The substrate processing apparatus of claim 1, wherein the nozzle installation part has an inner surface that extends at the same curvature as an inner surface of the reaction tube.

10. The substrate processing apparatus of claim 1, wherein a first distance that is the shortest horizontal distance between an inner surface of the nozzle installation part and a center of the reaction tube is the same as a second distance that is the shortest distance from a position of the inner surface of the reaction tube excluding the nozzle installation part to the center.

11. The substrate processing apparatus of claim 1, wherein the nozzle installation part comprises:
a pair of protrusion surfaces provided to protrude outward from a side surface of the reaction tube; and
an outer surface portion defined between the protrusion surfaces.

12. The substrate processing apparatus of claim 11, wherein the nozzle installation part comprises an installation member which is installed on an area surrounded by the pair of protrusion surfaces and the outer surface portion and in which a plurality of insertion parts are defined in an inner surface toward the processing space.

13. The substrate processing apparatus of claim 11, wherein, in the nozzle installation part,
the pair of protrusion surfaces and the outer surface portion are disposed on an outer surface of the nozzle installation part, and
the plurality of insertion parts are integrated with each other on the inner surface toward the processing space.

14. The substrate processing apparatus of claim 11, wherein the outer surface portion has the same curvature as an outer surface of the reaction tube.

15. The substrate processing apparatus of claim 1, wherein the reaction tube comprises an exhaust port provided at a position facing the nozzle installation part.

16. The substrate processing apparatus of claim 15, wherein the reaction tube is disposed to be line symmetric with respect to a virtual horizontal line connecting a center of the exhaust port to a center of the nozzle installation part on a plane.

17. The substrate processing apparatus of claim 1, wherein the gas injection nozzles are disposed to inject the process gas so that the plurality of gas injection holes defined in the vertical direction are parallel to each other.

18. The substrate processing apparatus of claim 1, further comprising an outer tube into which the reaction tube is accommodated to define an exhaust space between the outer tube and the reaction tube.

19. The substrate processing apparatus of claim 18, wherein a side surface of the outer tube, an inner surface of the nozzle installation part, and a side surface of the reaction tube have the same curvature as each other.
